(19) United States
(12) Patent Application Publication
(10) Pub. No.: US 2021/0343573 A1
(43) Pub. Date: Nov. 4, 2021

(54) ELECTRONIC COMPONENT, METHOD OF MANUFACTURING ELECTRONIC COMPONENT, AND ELECTRONIC COMPONENT PACKAGE

(71) Applicant: TDK CORPORATION, Tokyo (JP)

(72) Inventors: Hisayoshi WATANABE, Tokyo (JP); Yasuhiro ITO, Tokyo (JP); Takahiro IMAI, Tokyo (JP)

(73) Assignee: TDK CORPORATION, Tokyo (JP)

(21) Appl. No.: 17/224,480

(22) Filed: Apr. 7, 2021

(30) Foreign Application Priority Data
Apr. 30, 2020 (JP) 2020-080026

(51) Int. Cl. H01L 21/683; H01L 21/673; H01L 21/687

(52) U.S. Cl. CPC H01L 21/6836; H01L 21/6875; H01L 21/67306

(57) ABSTRACT

An electronic component includes a body and one or more protrusions. The body includes a first side surface, a second side surface opposite to the first side surface, and a first principal surface. The one or more protrusions are provided on at least one of the first side surface, the second side surface, or the first principal surface.

### CROSS REFERENCE TO RELATED APPLICATIONS

This application claims the benefit of Japanese Priority Patent Application No. 2020-080026 filed on Apr. 30, 2020, the entire contents of which are incorporated herein by reference.

### BACKGROUND

The technology relates to an electronic component, a method of manufacturing the electronic component, and an electronic component package containing a plurality of electronic components.

Electronic-component casings (carrier tapes) configured to contain, for example, a plurality of various electronic components to be installed in an electronic apparatus, and electronic component packages including such electronic-component casings with the electronic components contained therein have been proposed. For example, reference is made to Japanese Unexamined Patent Application Publication Nos. 2019-014538 and 2019-206364.

### SUMMARY

An electronic component according to one embodiment of the technology includes a body and one or more protrusions. The body includes a first side surface, a second side surface opposite to the first side surface, and a first principal surface. The one or more protrusions are provided on at least one of the first side surface, the second side surface, or the first principal surface.

An electronic component package according to one embodiment of the technology includes: the electronic component described above; a container; and a cover member. The container includes a recessed part containing the electronic component. The recessed part includes a first inner wall face that faces the first side surface of the body of the electronic component, and a second inner wall face that faces the second side surface of the body of the electronic component. The cover member covers the first principal surface of the body of the electronic component contained in the recessed part.

A method of manufacturing an electronic component according to one embodiment of the technology is a manufacturing method of an electronic component including a body and one or more protrusions. The method includes the following steps (1) to (6): (1) preparing a base that includes a surface and is transparent to ultraviolet radiation; (2) preparing a body array that includes a first principal surface and a second principal surface and includes a plurality of the bodies, the bodies being arranged side by side along the first principal surface and the second principal surface; (3) putting an ultraviolet curable resin on the surface of the base, the first principal surface of the body array, or both, and attaching the first principal surface of the body array to the surface of the base with the ultraviolet curable resin interposed therebetween; (4) cutting the body array attached to the base with the ultraviolet curable resin interposed therebetween and thereby separating every adjacent two of the bodies from each other; (5) irradiating the first principal surface with first ultraviolet light through the base; and (6) irradiating the second principal surface with second ultraviolet light from a side opposite to the base as viewed from the bodies to cure a first portion of the ultraviolet curable resin that adheres to the first principal surface, and thereby forming a first one of the one or more protrusions on the first principal surface.

A method of manufacturing an electronic component according to one embodiment of the technology is a manufacturing method of an electronic component including a body and one or more protrusions. The method includes the following steps (1) to (6): (1) preparing a base including a surface; (2) preparing a body array that includes a first principal surface and a second principal surface and includes a plurality of the bodies, the bodies being arranged side by side along the first principal surface and the second principal surface; (3) putting a thermosetting resin on the surface of the base, the first principal surface of the body array, or both, and attaching the first principal surface of the body array to the surface of the base with the thermosetting resin interposed therebetween; (4) cutting the body array attached to the base with the thermosetting resin interposed therebetween and thereby separating every adjacent two of the bodies from each other; (5) forming the one or more protrusions by applying heat to at least one of: a portion of the thermosetting resin that adheres to a side surface of each of the bodies formed by the cutting; a portion of the thermosetting resin that lies at a border part between the side surface and the first principal surface; or a portion of the thermosetting resin that adheres to the second principal surface; and (6) heating a portion of the thermosetting resin that lies between the surface of the base and the first principal surface.

### BRIEF DESCRIPTION OF THE DRAWINGS

The accompanying drawings are included to provide a further understanding of the disclosure and are incorporated in and constitute a part of this specification. The drawings illustrate example embodiments and, together with the specification, serve to explain the principles of the technology. FIG. 1 is cross-sectional diagram illustrating a partial configuration example of an electronic component package according to one example embodiment of the technology.

FIG. 2 is a planar diagram illustrating a partial planar configuration of the electronic component package illustrated in FIG. 1.

FIG. 3 is an enlarged perspective view of an electronic component illustrated in FIG. 1.

FIG. 4 is an enlarged cross-sectional view of a portion of the electronic component package illustrated in FIG. 1.

FIG. 5A is a cross-sectional diagram illustrating a step of a method of manufacturing the electronic component package illustrated in FIG. 1.

FIG. 5B is a cross-sectional diagram illustrating a step that follows the step of FIG. 5A.

FIG. 5C is a cross-sectional diagram illustrating a step that follows the step of FIG. 5B.

FIG. 5D is a cross-sectional diagram illustrating a step that follows the step of FIG. 5C.

FIG. 5E is a cross-sectional diagram illustrating a step that follows the step of FIG. 5D.

FIG. 5F is a partial cross-sectional diagram illustrating a step that follows the step of FIG. 5E.

FIG. 5G is a partial cross-sectional diagram illustrating a step that follows the step of FIG. 5F.

FIG. 6 is a schematic diagram illustrating a takeout apparatus that opens the electronic component package illustrated in FIG. 1 and takes out the electronic component.

FIG. 7A is a cross-sectional diagram illustrating a step of a method of manufacturing an electronic component according to a first modification example of the example embodiment of the technology.

FIG. 7B is a cross-sectional diagram illustrating a step that follows the step of FIG. 7A.

FIG. 7C is a cross-sectional diagram illustrating a step that follows the step of FIG. 7B.

FIG. 8A is an enlarged perspective view of an electronic component according to a second modification example of the example embodiment of the technology.

FIG. 8B is an enlarged perspective view of an electronic component according to a third modification example of the example embodiment of the technology.

FIG. 9A is a cross-sectional diagram illustrating a step of a method of manufacturing an electronic component according to a fourth modification example of the example embodiment of the technology.

FIG. 9B is a cross-sectional diagram illustrating a step that follows the step of FIG. 9A.

FIG. 9C is a cross-sectional diagram illustrating a step that follows the step of FIG. 9B.

FIG. 9D is a cross-sectional diagram illustrating a step that follows the step of FIG. 9C.

FIG. 9E is a cross-sectional diagram illustrating a step that follows the step of FIG. 9D.

FIG. 10A is a partial cross-sectional diagram illustrating a step of a method of manufacturing an electronic component according to a reference example.

FIG. 10B is a partial cross-sectional diagram illustrating how the electronic component according to the reference example illustrated in FIG. 10A is taken out of a casing.

### DETAILED DESCRIPTION

Further improvements in handleability, such as ease of taking out of an electronic component, are demanded of an electronic component package containing a plurality of electronic components and the electronic components to be contained in the electronic component package.

It is desirable to provide an electronic component and an electronic component package that are superior in handleability, and to provide a method of manufacturing such an electronic component package.

In the following, some example embodiments and modification examples of the technology are described in detail with reference to the accompanying drawings. Note that the following description is directed to illustrative examples of the disclosure and not to be construed as limiting the technology. Factors including, without limitation, numerical values, shapes, materials, components, positions of the components, and how the components are coupled to each other are illustrative only and not to be construed as limiting the technology. Further, elements in the following example embodiments which are not recited in a most-generic independent claim of the disclosure are optional and may be provided on an as-needed basis. The drawings are schematic and are not intended to be drawn to scale. Like elements are denoted with the same reference numerals to avoid redundant descriptions. Note that the description is given in the following order.
1. Example Embodiment

An example of an electronic component package including a plurality of electronic components each having a protrusion.
2. Modification Examples

### 1. Example Embodiment

### [Configuration of Electronic Component Package 1]

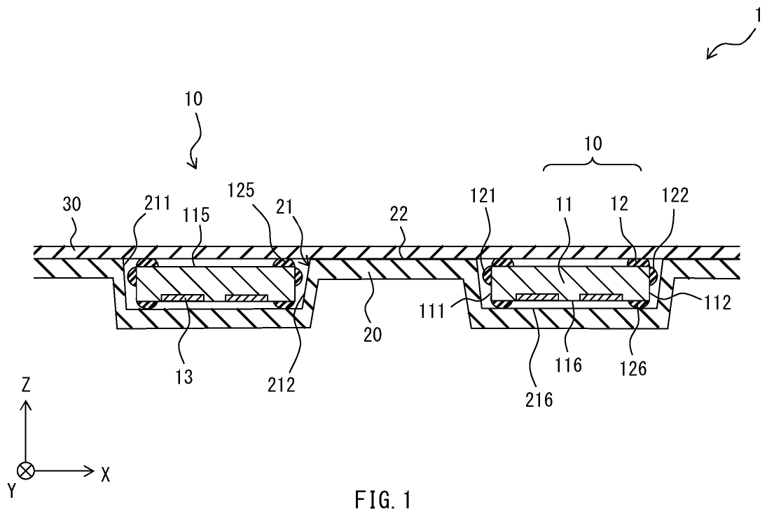

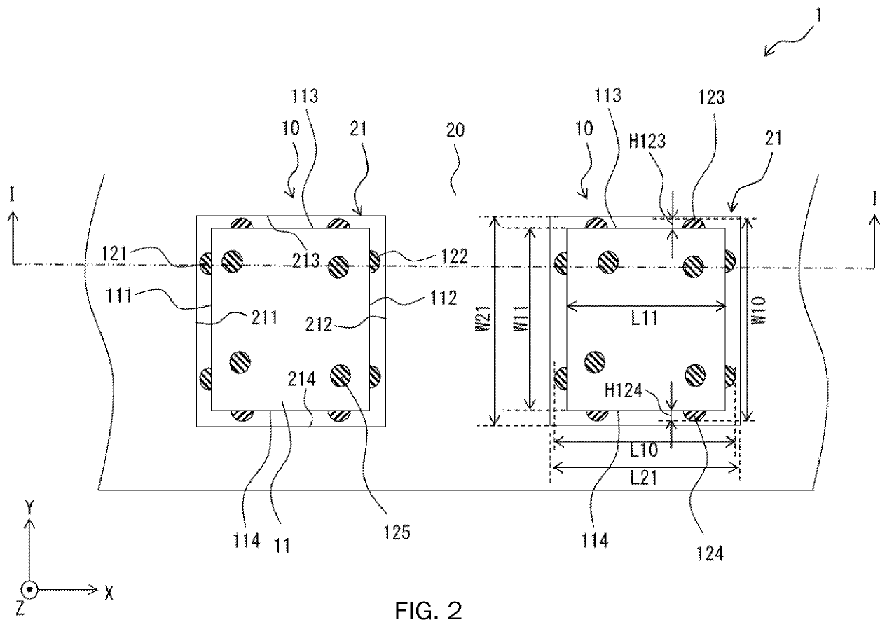

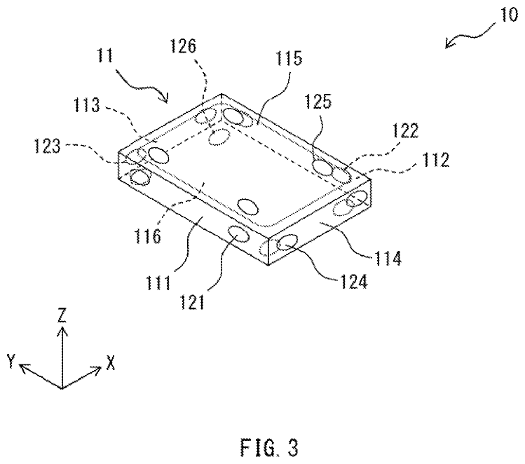

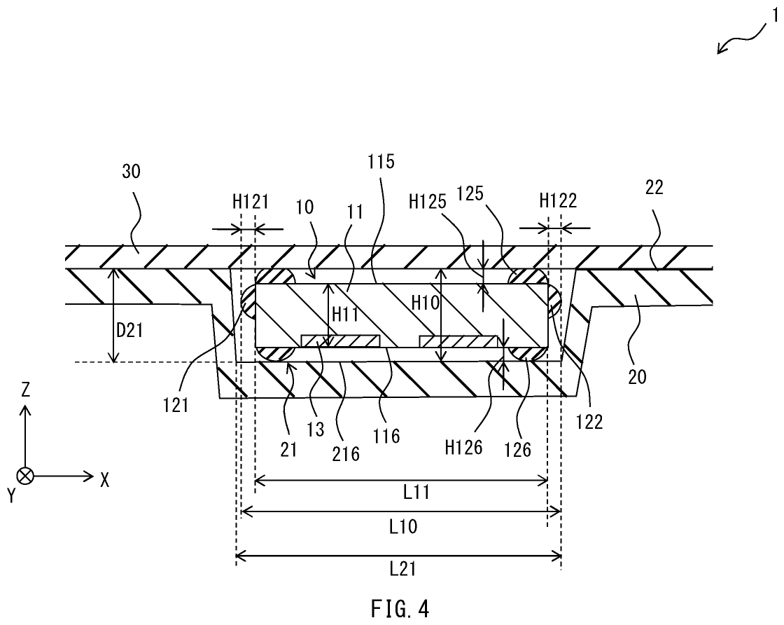

First, a configuration of an electronic component package 1 according to an example embodiment of the technology will be described with reference to FIGS. 1 to 4. FIG. 1 is a cross-sectional diagram illustrating a partial configuration example of the electronic component package 1. FIG. 2 is a planar diagram illustrating a partial configuration example of the electronic component package 1. Note that FIG. 2 omits the illustration of a sealing tape 30 (described later). FIG. 1 illustrates a cross section along line I-I in FIG. 2 as viewed in the direction of the arrows. FIG. 3 is an enlarged perspective view of one of electronic components 10 illustrated in FIG. 1. FIG. 4 is an enlarged cross-sectional view of one of the electronic components 10 and its vicinity illustrated in FIG. 1.

As illustrated in FIGS. 1 and 2, the electronic component package 1 may include a plurality of electronic components 10, a casing 20, and the sealing tape 30. The electronic components 10 may each correspond to a specific but non-limiting example of an “electronic component” according to one embodiment of the technology. The casing 20 may correspond to a specific but non-limiting example of a “container” according to one embodiment of the technology. The sealing tape 30 may correspond to a specific but non-limiting example of a “cover member” according to one embodiment of the technology.

### [Electronic Component 10]

The electronic component 10 includes a body 11, and may include a plurality of protrusions 121 to 126. Note that the protrusions 121 to 126 may hereinafter be collectively referred to as protrusions 12 in some cases. The body 11 may be, for example, an insulating substrate including an insulating material such as a resin or a metal oxide, or a semiconductor substrate including a semiconductor such as silicon. The body 11 may have, for example, a substantially cuboid contour and may include first to fourth side surfaces 111 to 114, a top surface 115, and a bottom surface 116. The top surface 115 may correspond to a specific but non-limiting example of a “first principal surface” of the body 11 according to one embodiment of the technology. The bottom surface 116 may correspond to a specific but non-limiting example of a “second principal surface” of the body 11 according to one embodiment of the technology. The top surface 115 and the bottom surface 116 may extend substantially parallel to each other. The first to fourth side surfaces 111 to 114 may each couple the top surface 115 and the bottom surface 116 to each other in a height direction. In the body 11, the second side surface 112 may be provided opposite to the first side surface 111, and the fourth side surface 114 may be provided opposite to the third side surface 113. The first side surface 111 and the second side surface 112 may extend substantially parallel to each other. The third side surface 113 and the fourth side surface 114 may extend substantially parallel to each other. Therefore, the first side surface 111 and the second side surface 112 may extend to be substantially orthogonal to the third side surface 113 and the fourth side surface 114.

An active component such as a light-emitting device or an oscillating device, a passive component such as a magnetic sensor device or a light receiving device, and/or another electronic component such as a capacitor or a resistor may be mounted on the body 11 of the electronic component 10. Furthermore, on the bottom surface 116, for example, an electrode terminal 13 may be provided for electrical coupling with an external apparatus.

The protrusions 121 to 126 may each be a structure including, for example, a cured ultraviolet curable resin as a constituent material. The protrusions 121 to 126 may adhere to the first to fourth side surfaces 111 to 114, the top surface 115, and the bottom surface 116, respectively. The protrusion 126 provided on the bottom surface 116 may be located off the electrode terminal 13 on the bottom surface 116. A similar configuration may apply to a case where the electrode terminal 13 is provided at a location other than the bottom surface 116, such as a case where the electrode terminal 13 is provided on any one of the first to fourth side surfaces 111 to 114 or on the top surface 115. That is, the protrusions 121 to 125 may be respectively located on the first to fourth side surfaces 111 to 114 and the top surface 115 without overlapping the electrode terminal 13. This makes it possible to prevent the protrusions 121 to 126 from interfering with electrical coupling to an external apparatus.

The body 11 may have a length L11, a width W11, and a height H11. For example, the length L11 may be a dimension in an X-axis direction, the width W11 may be a dimension in a Y-axis direction, and the height H11 may be a dimension in a Z-axis direction. The protrusion 121 provided on the first surface 111 may have a height H121 with respect to the first side surface 111. Likewise, the protrusions 122 to 124 provided on the second to fourth side surfaces 112 to 114 may have respective heights H122 to H124 with respect to the second to fourth side surfaces 112 to 114, respectively (see FIGS. 2 and 4). Further, the protrusion 125 provided on the top surface 115 may have a height H125 with respect to the top surface 115, and the protrusion 126 provided on the bottom surface 116 may have a height H126 with respect to the bottom surface 116. Note that the respective heights H121 to H126 of the protrusions 121 to 126 may be equal to or different from each other, or two or more but not all of them may be equal to each other. The entire electronic component 10 including the protrusions 121 to 126 may have a maximum length L10, a maximum width W10, and a maximum height H10.

### [Casing 20]

The casing 20 may be a long-length sheet extending in the X-axis direction, and may include a plurality of recessed parts 21. The recessed parts 21 may be arranged along the X-axis direction, being at a distance from each other. The casing 20 may include, for example, an insulating material such as polystyrene, polyethylene terephthalate, or polyvinyl chloride, or an electrically-conductive film including polystyrene, polyethylene terephthalate, or polyvinyl chloride as a constituent material. The recessed parts 21 may each be configured to contain the electronic component 10, and may each include first to fourth inner wall faces 211 to 214 (see FIGS. 1 and 2) that face the first to fourth side surfaces 111 to 114, respectively. The recessed parts 21 may each further include a bottom surface 216 facing the bottom surface 116 (see FIGS. 1 and 4). The recessed parts 21 may each define a substantially cuboid-shaped space having a length L21, a width W21, and a depth D21. In order for each of the recessed parts 21 to be able to contain the electronic component 10 with the protrusions 12 on the body 11, the length L21 may be greater than the maximum length L10, the width W21 may be greater than the maximum width W10, and the depth D21 may be greater than the maximum height H10.

### [Sealing Tape 30]

The sealing tape 30 may be, for example, a resin film, and may adhere to a surface 22 of the casing 20 via an adhesive or a glue, or by thermocompression bonding of the sealing tape. The sealing tape 30 may be a band-shaped member that closes openings of the recessed parts 21 of the casing 20 and seals the recessed parts 21. The sealing tape 30 may be configured to seal the plurality of recessed parts 21 collectively by adhering to the surface 22 of the casing 20. It is to be noted that the recessed parts 21 may be individually sealed by multiple pieces of sealing tape 30. In the electronic component package 1, the recessed parts 21 of the casing 20 may be sealed by the sealing tape 30 with the electronic components 10 being contained in the recessed parts 21.

### [Method of Manufacturing Electronic Component Package 1]

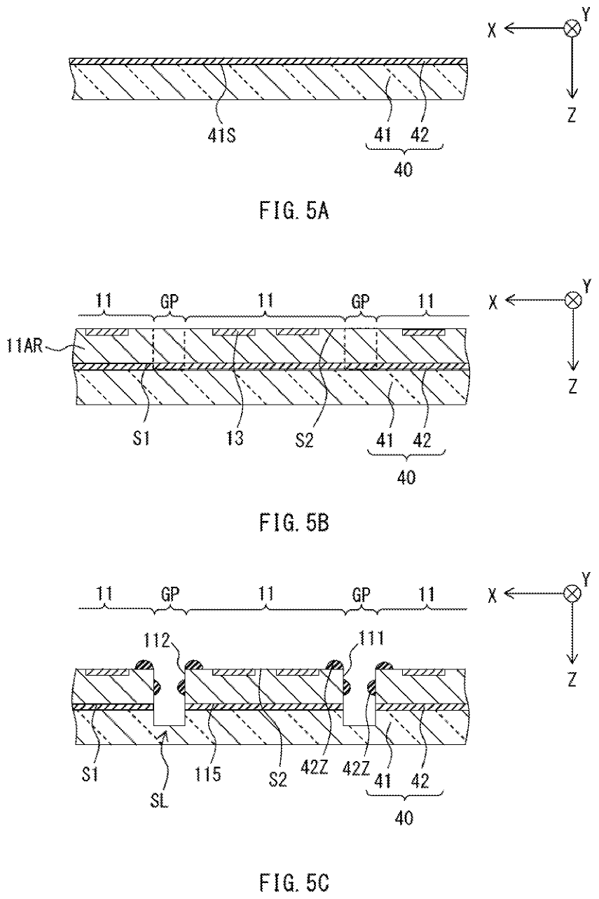

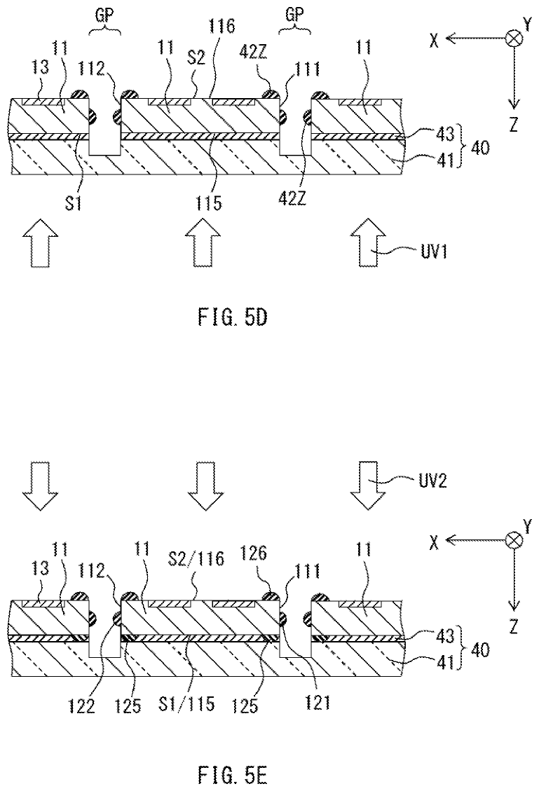

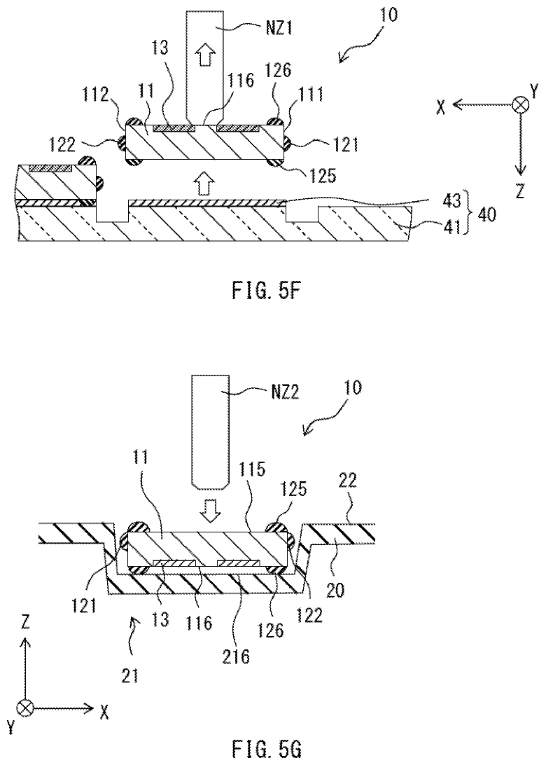

Next, a method of manufacturing the electronic component package 1 will be described with reference to FIGS. 5A to 5G. A method of manufacturing the electronic component 10 will also be described together. FIGS. 5A to 5G are cross-sectional diagrams each illustrating a step of the method of manufacturing the electronic component package 1. Note that FIGS. 5A to 5G each illustrate an XZ cross section orthogonal to a Y-axis.

First, as illustrated in FIG. 5A, a dicing tape 40 extending in both of the X-axis direction and the Y-axis direction may be prepared. The dicing tape 40 may include a transparent resin film 41, and an adhesive layer 42 provided on a surface 41S of the transparent resin film 41. The transparent resin film 41 may be a sheet-like member transparent to ultraviolet light. The adhesive layer 42 may include an ultraviolet curable resin. It is to be noted that a dicing tape including the transparent resin film 41 and the adhesive layer 42 integrally formed in advance may be prepared as the dicing tape 40, or the adhesive layer 42 may be formed by applying an adhesive onto the surface 41S of the transparent resin film 41.

Next, as illustrated in FIG. 5B, a body array 11AR including a plurality of bodies 11 is prepared. The bodies 11 may be arranged side by side in both of the X-axis direction and the Y-axis direction with a gap region GP interposed between every two adjacent bodies 11. The body array 11AR includes a first principal surface Si and a second principal surface S2. The respective top surfaces 115 of the bodies 11 constitute the first principal surface Si of the body array 11AR. The respective bottom surfaces 116 of the bodies 11 constitute the second principal surface S2 of the body array 11AR. Then, the first principal surface S1 of the body array 11AR is attached to the surface 41S of the transparent resin film 41 with the adhesive layer 42 interposed therebetween.

Next, as illustrated in FIG. 5C, the body array 11AR attached to the transparent resin film 41 with the adhesive layer 42 therebetween is cut to thereby separate every two adjacent bodies 11 from each other. At this time, for example, a slit SL may be formed by applying a rotating dicing blade to the gap region GP of the body array 11AR and moving the blade in a +Z direction until it reaches the transparent resin film 41. The transparent resin film 41 may not be completely cut and the plurality of bodies 11 may thus remain held by the single transparent resin film 41 with the adhesive layer 42 interposed between the transparent resin film 41 and the plurality of bodies 11. Upon the cutting of the body array 11AR with the rotating dicing blade, part of the ultraviolet curable resin included in the adhesive layer 42 may fly off to adhere to the first to fourth side surfaces 111 to 114 of each of the bodies 11 separated from adjacent bodies 11, and onto the second principal surface S2, as deposits 42Z.

Thereafter, as illustrated in FIG. 5D, the first principal surface S1, that is, the top surface 115 of each of the bodies 11 is irradiated with first ultraviolet light UV1 through the transparent resin film 41. This causes the adhesive layer 42 to be cured to some extent into a semi-cured layer 43. The ultraviolet curable resin included in the adhesive layer 42 gradually loses adhesiveness as curing proceeds. In this step, an ultraviolet radiation dose not enough to completely cure the ultraviolet curable resin included in the adhesive layer 42, that is, an ultraviolet radiation dose enough to change the adhesive layer 42 into the semi-cured layer 43 that retains adhesiveness enough to hold the bodies 11 may be supplied by the first ultraviolet light UV1.

Further, as illustrated in FIG. 5E, the second principal surface S2, that is, the bottom surface 116 of each of the bodies 11 is irradiated with second ultraviolet light UV2 from a side opposite to the transparent resin film 41 as viewed from the bodies 11. This causes the deposits 42Z on the first to fourth side surfaces 111 to 114 and on the second principal surface S2 (the bottom surface 116) to be cured into the protrusions 12 (121 to 124 and 126). Here, an ultraviolet radiation dose enough to cause the deposits 42Z to sufficiently lose their adhesiveness may be supplied by the second ultraviolet light UV2. The second ultraviolet light UV2 may therefore be higher in intensity than the first ultraviolet light UV1. The irradiation with the second ultraviolet light UV2 causes portions of the semi-cured layer 43 between the top surface 115 of each of the bodies 11 and the transparent resin film 41, such as portions at and near borders between the top surface 115 and the first to fourth side surfaces 111 to 114, to be also irradiated and cured. As a result, the protrusions 125 are formed at peripheral parts of the top surface 115, that is, at border parts of the top surface 115 intersecting the first to fourth side surfaces 111 to 114.

Thereafter, as illustrated in FIG. 5F, the bottom surface 116 of the body 11 may be sucked by a suction nozzle NZ1 to pick up the electronic components 10 one by one from the dicing tape 40.

Thereafter, as illustrated in FIG. 5G, the top surface 115 of the body 11 may be sucked by another suction nozzle NZ2. The electronic component 10 may thus be passed from the suction nozzle NZ1 to the suction nozzle NZ2. Then, the electronic component 10 may be placed into the recessed part 21 of the casing 20 in an inverted orientation.

Lastly, the sealing tape 30 may be applied to the surface 22 to seal the recessed parts 21 each containing the electronic component 10. The electronic component package 1 may be completed thus.

### [Method of Taking Out Electronic Component 10]

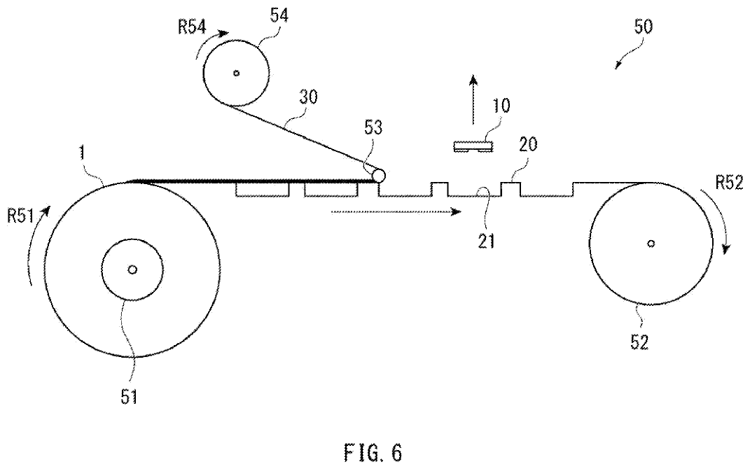

Next, a method of opening the electronic component package 1 and a method of taking out the electronic component 10 will be described with reference to FIG. 6. FIG. 6 is a schematic diagram illustrating a takeout apparatus 50 that opens the electronic component package 1 and takes out the electronic component 10.

The takeout apparatus 50 may include a feeder unit 51, a first wind-up unit 52, a guide roller 53, and a second wind-up unit 54. The feeder unit 51 may be a unit that, upon mounting of a wound-up roll of the electronic component package 1 thereon, rotates to feed the electronic components 10 contained in the recessed parts 21 of the electronic component package 1 one by one. The first wind-up unit 52 may be a unit that winds up the casing 20 of the electronic component package 1. The guide roller 53 may be a rotating body that guides the sealing tape 30 of the electronic component package 1 to the second wind-up unit 54 while peeling the sealing tape 30 away from the casing 20. The second wind-up unit 54 may be a unit that winds up the sealing tape 30 guided by the guide roller 53. In the takeout apparatus 50, the feeder unit 51, the first wind-up unit 52, and the second wind-up unit 54 may rotate in conjunction with each other in their respective rotation directions R51, R52, and R54 indicated by arrows to thereby cause: the sealing tape 30 to be peeled away from the casing 20 at the guide roller 53; the casing 20 to be wound up at the first wind-up unit 52; and the sealing tape 30 to be wound up at the second wind-up unit 54. Because the recessed parts 21 of the casing 20 may each become open between the guide roller 53 and the first wind-up unit 52, the electronic component 10 may be taken out at this stage. The electronic component 10 thus taken out may be mounted on a substate or the like. How to take out the electronic component 10 is not particularly limited, and one example method thereof is suction by using a suction nozzle or the like.

### [Example Effects of Electronic Component Package 1]

As described above, according to the electronic component package 1 of the present example embodiment, the electronic component 10 may include the protrusions 121 to 124 on the first to fourth side surfaces 111 to 114 of the body 11, respectively. This configuration is expected to provide the following effect. That is, by providing the protrusions 121 to 124 on the first to fourth side surfaces 111 to 114, respectively, it is possible for the electronic component 10 to remain a correct posture without tilting when the electronic component 10 is taken out of the recessed part 21 of the casing 20 by the suction nozzle NZ1.

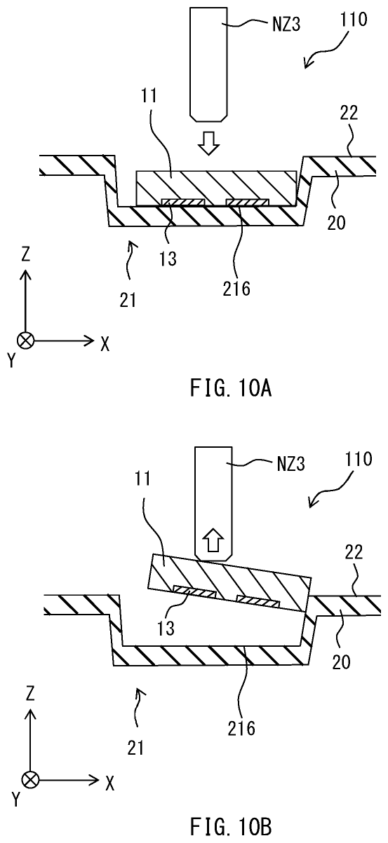

In contrast, in a case where the protrusions 121 and 124 are not provided on the first to fourth side surfaces 111 to 114 as in an electronic component 110 according to a reference example illustrated in FIG. 10A, for example, a center position of the body 11 tends to be displaced with respect to a center position of the recessed part 21 in an XY plane. This can cause the electronic component 110 to become tilted, as illustrated in FIG. 10B, upon suction by a suction nozzle NZ3 for taking out the electronic component 110. As a result, the electronic component 110 can fall. Further, even if the electronic component 110 may not fall, there is concern about the possibility of eventual failure to move the electronic component 110 in a correct posture to a correct location. One reason for the occurrence of a tilt of the electronic component 110 upon the suction thereof by the suction nozzle NZ3 is considered to be that the first to fourth inner wall faces 211 to 214 of the recessed part 21 and the first to fourth side surfaces 111 to 114 of the body 11 tend to come into intimate contact with each other, or that a suction position of the suction nozzle NZ3 with respect to the body 11 greatly deviates from the center position of the body 11 in the XY plane. One reason for the deviation of the suction position of the suction nozzle NZ3 from the center position of the body 11 is that the alignment of the suction nozzle NZ3 is typically performed with respect to the center position of the recessed part 21 in the XY plane.

According to the present example embodiment, the presence of the protrusions 121 to 124 makes it possible to bring the center position of the electronic component 10 sufficiently close to the center position of the recessed part 21 in the XY plane. This allows the suction nozzle NZ1 to suck the electronic component 10 at an appropriate suction position and allows the electronic component 10 to maintain a correct posture without tilting during the operation for takeout from the casing 20. As a result, it is possible to move the electronic component 10 in a correct posture to a correct location. The electronic component 10 and the electronic component package 1 according to the present example embodiment thus achieve superior handleability.

In the present example embodiment, the electronic component 10 may include the protrusions 125 on the top surface 115 of the body 11. This configuration is expected to provide the following effect. That is, by providing the protrusions 125 on the top surface 115, it is possible to prevent the electronic component 10 from adhering to a back side of the sealing tape 30 by an electrostatic force when the sealing tape 30 is peeled away from the casing 20. This facilitates smooth takeout operation on the electronic component 10.

In the present example embodiment, the electronic component 10 may include the protrusions 126 on the bottom surface 116 of the body 11. This makes it possible to prevent the electronic component 10 contained in the recessed part 21 of the casing 20 from adhering to the bottom surface 216 of the recessed part 21 by an electrostatic force. Accordingly, it is possible to prevent a trouble in taking out the electronic component 10 from the recessed part 21 of the casing 20 by using the suction nozzle NZ1 or the like.

In the present example embodiment, the protrusions 121 to 126 may be located off the electrode terminal 13 on the body 11. This makes it possible to prevent the protrusions 121 to 126 from interfering with electrical coupling to an external apparatus.

In the present example embodiment, the body array 11AR that is attached to the transparent resin film 41, with the adhesive layer 42 including an ultraviolet curing resin interposed therebetween, is cut to thereby separate every two adjacent bodies 11 from each other, and thereafter, the first principal surface Si is irradiated with the first ultraviolet light UV1 and the second principal surface S2 is irradiated with the second ultraviolet light UV2. It is thereby possible to form the protrusions 121 to 126 on the first to fourth side surfaces 111 to 114, the top surface 115, and the bottom surface 116, respectively, of the body 11. This allows relatively easy and efficient manufacture of the electronic component 10 and the electronic component package 1 that are superior in handleability as described above.

In the present example embodiment, the deposits 42Z on the first to fourth side surfaces 111 to 114, the top surface 115, and the bottom surface 116 of the body 11 may be cured by irradiating the second principal surface S2 with the second ultraviolet light UV2 as well as irradiating the first principal surface S1 with the first ultraviolet light UV1. This causes the deposits 42Z having adhesiveness to change into the protrusions 12 having no adhesiveness, thus making it possible to avoid adhesion to the recessed parts 21 of the casing 20 or to the sealing tape 30. This consequently makes it possible to open the electronic component package 1 and take out the electronic component 10 smoothly with the takeout apparatus 50.

### 2. Modification Examples

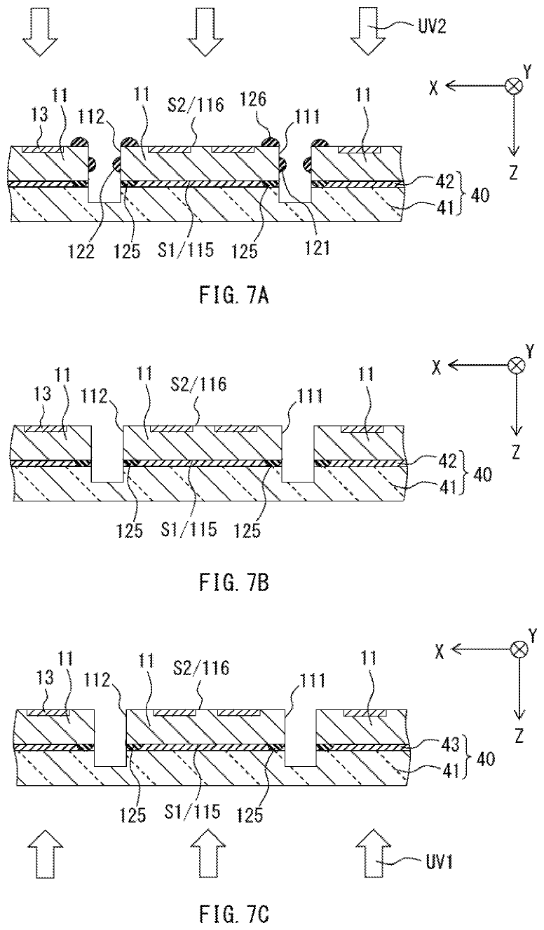

The technology has been described above with reference to the example embodiment. However, the technology is not limited thereto, and may be modified in a variety of ways. For example, the foregoing example embodiment has been described with reference to an example case where the protrusions 121 to 126 are provided on the first to fourth side surfaces 111 to 114, the top surface 115, and the bottom surface 116 of the body 11. However, the electronic component 10 may include only the protrusions 125 on the top surface 115 of the body 11. In such a case, the electronic component 10 may be fabricated as follows. The following will describe a method of manufacturing an electronic component 10 according to a first modification example of the foregoing example embodiment of the technology with reference to FIGS. 7A to 7C. FIGS. 7A to 7C are cross-sectional diagrams each illustrating a step of the method of manufacturing the electronic component 10 according to the first modification example of the foregoing example embodiment of the technology.

First, after going through the procedure illustrated in FIGS. 5A to 5C described in relation to the foregoing example embodiment, as illustrated in FIG. 7A, the second principal surface S2, that is, the bottom surface 116 of each of the bodies 11 is irradiated with the second ultraviolet light UV2 from the side opposite to the transparent resin film 41 as viewed from the bodies 11. This causes the deposits 42Z on the first to fourth side surfaces 111 to 114 and on the second principal surface S2 (the bottom surface 116) to be cured into the protrusions 12 (121 to 124 and 126). Here, an ultraviolet radiation dose enough to cause the deposits 42Z to sufficiently lose their adhesiveness may be supplied by the second ultraviolet light UV2. The irradiation with the second ultraviolet light UV2 causes portions of the adhesive layer 42 between the top surface 115 of each of the bodies 11 and the transparent resin film 41, such as portions at and near borders between the top surface 115 and the first to fourth side surfaces 111 to 114, to be also irradiated and cured. As a result, the protrusions 125 are formed at peripheral parts of the top surface 115, that is, at border parts of the top surface 115 intersecting the first to fourth side surfaces 111 to 114.

Next, as illustrated in FIG. 7B, the protrusions 121 to 124 and 126 are removed by washing with water or by air blowing.

Next, as illustrated in FIG. 7C, the first principal surface S1, that is, the top surface 115 of each of the bodies 11 is irradiated with the first ultraviolet light UV1 through the transparent resin film 41. This causes the adhesive layer 42 to be cured to some extent into the semi-cured layer 43. In this step, an ultraviolet radiation dose enough to change the adhesive layer 42 into the semi-cured layer 43 that retains adhesiveness enough to hold the bodies 11 may be supplied by the first ultraviolet light UV1.

Thereafter, by the procedure illustrated in FIGS. 5F and 5G, the electronic components 10 may be placed into the recessed parts 21 of the casing 20 to complete the method of manufacturing he electronic component package 1 according to the modification example.

As described above, even in a case where the electronic component 10 is provided with the protrusions 125 on the top surface 115 only, it is possible to prevent the electronic component 10 from adhering to the back side of the sealing tape 30 by an electrostatic force when the sealing tape 30 is peeled away from the casing 20. This facilitates smooth takeout operation on the electronic component 10.

In the above-described procedure, irradiation of the second principal surface S2 with the second ultraviolet light UV2 is followed by water-washing or air blowing, and thereafter the first principal surface S1 is irradiated with the first ultraviolet light UV1. A reason for performing the steps in such an order is as follows. If the irradiation of the first principal surface Si with the first ultraviolet light UV1 precedes the water-washing or air blowing, the mechanical load to be applied to the electronic component 10 during the water-washing or air blowing can cause the electronic component 10 to become detached from the transparent resin film 41 or can change the posture of the electronic component 10 with respect to the transparent resin film 41. One reason for this is that the adhesiveness of the semi-cured layer 43 is lower than that of the adhesive layer 42. Thus, by performing the water-washing or air blowing on the electronic component 10 in a state where sufficient adhesion is retained by the adhesive layer 42, it is possible to prevent the electronic component 10 from becoming detached or displaced from the transparent resin film 41. In view of this, the irradiation of the second principal surface S2 with the second ultraviolet light UV2 and the water-washing or air blowing may precede the irradiation of the first principal surface S1 with the first ultraviolet light UV1.

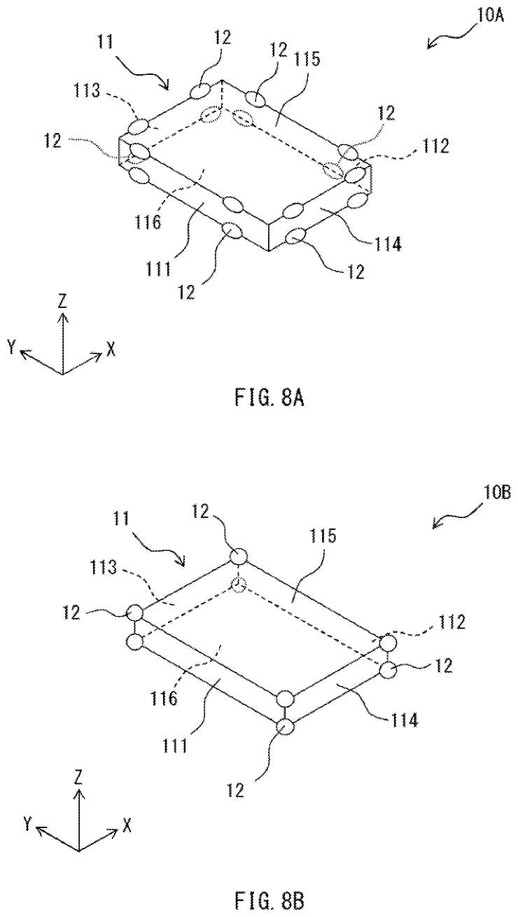

Further, although the foregoing example embodiment has been described with reference to an example case of providing the protrusions 121 to 126 on the first to fourth side surfaces 111 to 114, the top surface 115, and the bottom surface 116, respectively, the protrusion 12 may be provided, for example, on a border part between two adjacent surfaces as in an electronic component 10A according to a second modification example of the example embodiment of the technology illustrated in FIG. 8A. Alternatively, as in an electronic component 10B according to a third modification example of the example embodiment of the technology illustrated in FIG. 8B, the protrusion 12 may be provided on a corner defined by three adjacent surfaces.

Further, in some embodiments of the technology, one or more protrusions 12 may be provided on at least one of the six surfaces of the body 11, that is, at least one of the first side surface 111, the second side surface 112, the third side surface 113, the fourth side surface 114, the top surface 115, or the bottom surface 116 of the body 11. In a specific but non-limiting example, one or more protrusions 12 may be provided on each of two or more of the six surfaces of the body 11, such as both of the first side surface 111 and the second surface 112 opposed to each other, or both of the third side surface 113 and the fourth side surface 114 opposed to each other, among the first to fourth side surfaces 111 to 114. Providing one or more protrusions 12 on both of two side surfaces opposed to each other makes it possible to bring the center position of the electronic component 10 closer to the center position of the recessed part 21 than in a case of providing one or more protrusions 12 on only one of the first to fourth side surfaces 111 to 114, for example. Further, providing one or more protrusions 12 on all of the first to fourth side surfaces 111 to 114 makes it possible to bring the center position of the electronic component 10 even closer to the center position of the recessed part 21. Further, by providing one or more protrusions 12 on each of the top surface 115 and any one or more of the first to fourth side surfaces 111 to 114, it is possible to bring the center position of the electronic component 10 close to the center position of the recessed part 21 and also to prevent the electronic component 10 from adhering to the back side of the sealing tape 30. Further, by providing one or more protrusions 12 on each of the bottom surface 116 and any one or more of the first to fourth side surfaces 111 to 114, it is possible to bring the center position of the electronic component 10 close to the center position of the recessed part 21 and also to prevent the electronic component 10 from adhering to the bottom surface 216 of the recessed part 21. Further, by providing one or more protrusions 12 on all of the first to fourth side surfaces 111 to 114, the top surface 115, and the bottom surface 116 of the body 11 as in the foregoing example embodiment, it is possible to achieve all of the effects described above.

Although the foregoing example embodiment has been described with reference to an example case of providing the plurality of protrusions 12 on each of the first to fourth side surfaces 111 to 114, the top surface 115, and the bottom surface 116, embodiments of the technology are not limited thereto. For example, a single protrusion 12 may be provided on at least one of the first side surface 111, the second side surface 112, the third side surface 113, the fourth side surface 114, the top surface 115, or the bottom surface 116. Further, the number of the protrusions 12 to be provided on each of the first to fourth side surfaces 111 to 114, the top surface 115, and the bottom surface 116 is not limited to the examples thereof described above.

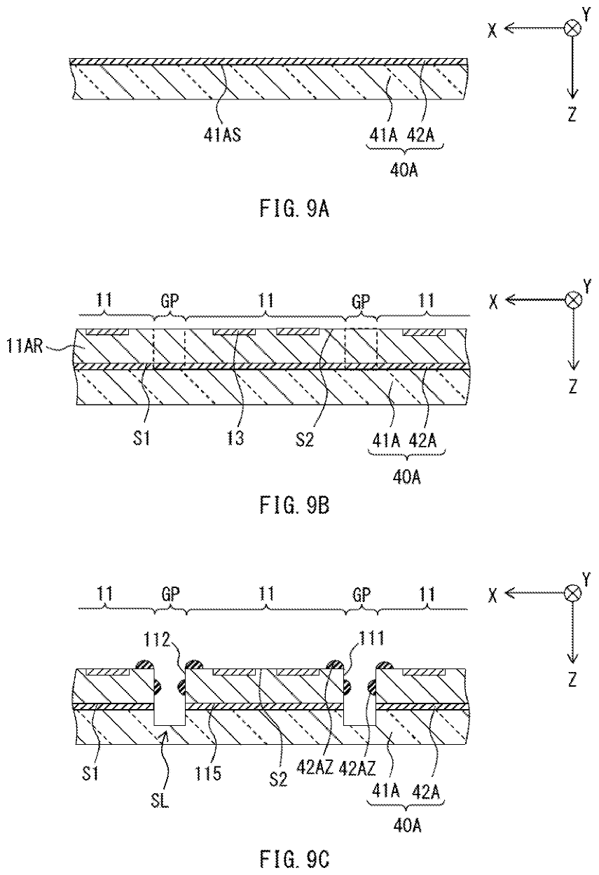

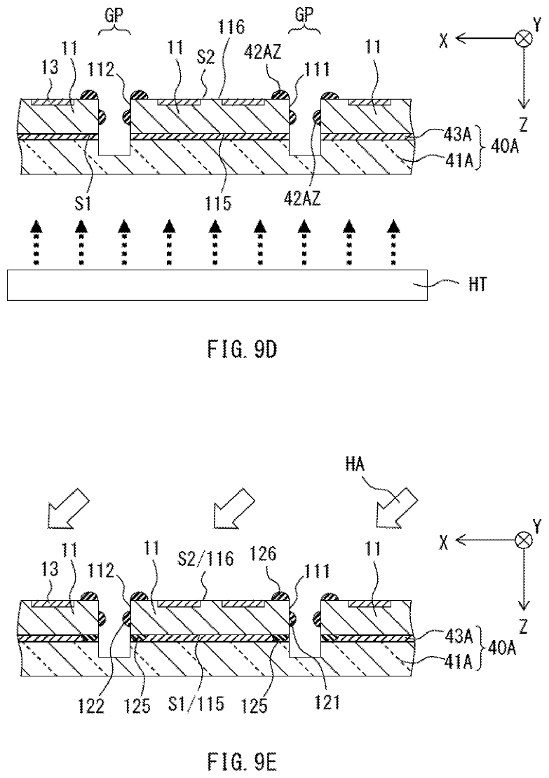

The foregoing example embodiment has been described with reference to an example case of using an ultraviolet curable resin in which curing proceeds by ultraviolet irradiation. However, in some embodiments of the technology, a thermosetting resin in which curing proceeds by heat treatment may be used in place of the ultraviolet curable resin. In such a case, the electronic component 10 may be manufactured as follows. In the following, a method of manufacturing the electronic component 10 using a thermosetting resin will be described with reference to FIGS. 9A to 9G.

First, as illustrated in FIG. 9A, as with the case of using the ultraviolet curable resin, a dicing tape 40A extending in both of the X-axis direction and the Y-axis direction may be prepared as the base. The dicing tape 40A may include, for example, a resin film 41A, and an adhesive layer 42A including a thermosetting rein and provided on a surface 41AS of the resin film 41A. The resin film 41A need not necessarily be transparent to ultraviolet radiation. It is to be noted that a dicing tape including the resin film 41A and the adhesive layer 42A integrally formed in advance may be prepared as the dicing tape 40A, or the adhesive layer 42A may be formed by applying an adhesive onto the surface 41AS of the resin film 41A.

Next, as illustrated in FIG. 9B, the body array 11AR including a plurality of bodies 11 is prepared. The bodies 11 may be arranged side by side in both of the X-axis direction and the Y-axis direction with the gap region GP interposed between every two adjacent bodies 11. The respective top surfaces 115 of the bodies 11 constitute the first principal surface S1 of the body array 11AR. The respective bottom surfaces 116 of the bodies 11 constitute the second principal surface S2 of the body array 11AR. Then, the first principal surface Si of the body array 11AR is attached to the surface 41AS of the resin film 41A with the adhesive layer 42A interposed therebetween.

Next, as illustrated in FIG. 9C, the body array 11AR attached to the resin film 41A with the adhesive layer 42A interposed therebetween is cut to thereby separate every two adjacent bodies 11 from each other. At this time, for example, the slit SL may be formed by applying a rotating dicing blade to the gap region GP of the body array 11AR and moving the blade in the +Z direction until it reaches the resin film 41A. The resin film 41A may not be completely cut and the plurality of bodies 11 may thus remain held by the single resin film 41A with the adhesive layer 42A interposed between the resin film 41A and the bodies 11. Upon the cutting of the body array 11AR with the rotating dicing blade, part of the thermosetting resin included in the adhesive layer 42A may fly off to adhere to the first to fourth side surfaces 111 to 114 of each of the bodies 11 separated from adjacent bodies 11, and onto the second principal surface S2, as deposits 42AZ.

Thereafter, as illustrated in FIG. 9D, the bodies 11 each separated from adjacent bodies 11 and the dicing tape 40 holding the bodies 11 may be put into an electric furnace or the like to apply heat onto the bodies 11 and the dicing tape 40A with a heater HT. This causes the adhesive layer 42A to be cured to some extent into a semi-cured layer 43A. The thermosetting resin included in the adhesive layer 42A gradually loses adhesiveness as curing proceeds. In this step, an amount of heat not enough to completely cure the thermosetting resin included in the adhesive layer 42A, that is, an amount of heat enough to change the adhesive layer 42A into the semi-cured layer 43A that retains adhesiveness enough to hold the bodies 11 may be supplied by the heater HT.

Further, as illustrated in FIG. 9E, hot air HA may be applied with a dryer or the like from a side opposite to the resin film 41A as viewed from the bodies 11. This causes the deposits 42AZ on the first to fourth side surfaces 111 to 114 and the second principal surface S2 (the bottom surface 116) of the bodies 11 to be cured into the protrusions 12 (121 to 124 and 126). Here, an amount of heat enough to cause the deposits 42AZ to sufficiently lose their adhesiveness may be supplied by applying the hot air HA. The application of the hot air HA with a dryer or the like from the side opposite to the resin film 41A as viewed from the bodies 11 causes portions of the semi-cured layer 43A between the top surface 115 of each of the bodies 11 and the resin film 41A, such as portions at and near borders between the top surface 115 and the first to fourth side surfaces 111 to 114, to be also heated and cured. As a result, the protrusions 125 are formed at peripheral parts of the top surface 115, that is, at border parts of the top surface 115 intersecting the first to fourth side surfaces 111 to 114.

The electronic component 10 using the thermosetting resin may be completed by the above-described procedure.

It is to be noted that the electronic component 10 having the protrusions 12 including the thermosetting resin is manufacturable not only by the above-described manufacturing method but also another manufacturing method described below. For example, after applying heat enough to cause the adhesive layer 42A to be cured to some extent into the semi-cured layer 43A as illustrated in FIG. 9D, the following procedure may be performed. That is, after the bodies 1 with the deposits 42AZ adhering thereto are detached from the dicing tape 40A, they are subjected to heat treatment in an electric furnace or the like. The deposits 42AZ may be thereby cured into the protrusions 12. Such a method where heat treatment to cure the deposits 42AZ is performed after detachment of the bodies 11 from the dicing tape 40A may be suitable in a case where the bodies 11 are relatively small in dimensions.

Further, although the foregoing example embodiment has been described with reference to an example case where the deposits generated in the course of separating every two adjacent bodies 11 from each other are cured by ultraviolet light to form the protrusions, embodiments of the technology are not limited thereto. For example, the protrusions may be formed by chipping or the like after the bodies 11 are separated from each other.

The technology encompasses any possible combination of some or all of the various embodiments and the modifications described herein and incorporated herein.

It is possible to achieve at least the following configurations from the foregoing embodiments and modification examples of the technology.
(1)

An electronic component including:

a body including a first side surface, a second side surface opposite to the first side surface, and a first principal surface; and

one or more protrusions, the one or more protrusions being provided on at least one of the first side surface, the second side surface, or the first principal surface.
(2)

The electronic component according to (1), in which

the body further includes a second principal surface opposite to the first principal surface, and

the one or more protrusions are provided also on the second principal surface.
(3)

The electronic component according to (2), in which

the body further includes a third side surface that couples the first side surface and the second side surface to each other, and a fourth side surface opposite to the third side surface, and

the one or more protrusions are provided also on the third side surface, the fourth side surface, or both.
(4)

The electronic component according to (3), further including an electrode provided on at least one of the first principal surface, the first side surface, the second side surface, the third side surface, the fourth side surface, or the second principal surface of the body,

in which the one or more protrusions are located off the electrode.
(5)

The electronic component according to any one of (1) to (4), in which the one or more protrusions each include an ultraviolet curable resin or a thermosetting resin.
(6)

The electronic component according to any one of (1) to (5), in which the at least one protrusion is provided on a first border part between the first side surface and the first principal surface, a second border part between the second side surface and the first principal surface, or both.
(7)

An electronic component package comprising:

an electronic component that includes:
a body including a first side surface, a second side surface opposite to the first side surface, and a first principal surface; and
one or more protrusions, the one or more protrusions being provided at least on at least one of the first side surface, the second side surface, or the first principal surface;

a container that includes a recessed part containing the electronic component, the recessed part including a first inner wall face that faces the first side surface of the body of the electronic component, and a second inner wall face that faces the second side surface of the body of the electronic component; and

a cover member covering the first principal surface of the body of the electronic component contained in the recessed part.
(8)

The electronic component package according to (7), in which

the body of the electronic component further includes a second principal surface opposite to the first principal surface,

the one or more protrusions are provided also on the second principal surface, and

the recessed part further includes a bottom surface facing the second principal surface.
(9)

A method of manufacturing an electronic component that includes a body and one or more protrusions, the method including:

preparing a base that includes a surface and is transparent to ultraviolet radiation;

preparing a body array that includes a first principal surface and a second principal surface and includes a plurality of the bodies, the bodies being arranged side by side along the first principal surface and the second principal surface;

putting an ultraviolet curable resin on the surface of the base, the first principal surface of the body array, or both, and attaching the first principal surface of the body array to the surface of the base with the ultraviolet curable resin interposed therebetween;

cutting the body array attached to the base with the ultraviolet curable resin interposed therebetween and thereby separating every adjacent two of the bodies from each other;

irradiating the first principal surface with first ultraviolet light through the base; and

irradiating the second principal surface with second ultraviolet light from a side opposite to the base as viewed from the bodies to cure a first portion of the ultraviolet curable resin that adheres to the first principal surface, and thereby forming a first one of the one or more protrusions on the first principal surface.
(10)

The method according to (9), further including removing, by washing with water, a second one of the one or more protrusions that results from a second portion of the ultraviolet curable resin adhering to the second principal surface and thereafter curing by irradiation of the second principal surface with the second ultraviolet light. (11)

The method according to (9) or (10), in which the irradiating of the first principal surface with the first ultraviolet light and the irradiating of the second principal surface with the second ultraviolet light result in curing of a third portion of the ultraviolet curable resin that adheres to a border part between a side surface of each of the bodies formed by the cutting and the first principal surface intersecting the side surface, and thereby further form a third one of the one or more protrusions on the border part.
(12)

The method according to any one of (9) to (11), in which the second ultraviolet light is made higher in intensity than the first ultraviolet light.
(13)

A method of manufacturing an electronic component that includes a body and one or more protrusions, the method including:

preparing a base including a surface;

preparing a body array that includes a first principal surface and a second principal surface and includes a plurality of the bodies, the bodies being arranged side by side along the first principal surface and the second principal surface;

putting a thermosetting resin on the surface of the base, the first principal surface of the body array, or both, and attaching the first principal surface of the body array to the surface of the base with the thermosetting resin interposed therebetween;

cutting the body array attached to the base with the thermosetting resin interposed therebetween and thereby separating every adjacent two of the bodies from each other;

forming the one or more protrusions by applying heat to at least one of: a portion of the thermosetting resin that adheres to a side surface of each of the bodies formed by the cutting; a portion of the thermosetting resin that lies at a border part between the side surface and the first principal surface; or a portion of the thermosetting resin that adheres to the second principal surface; and

heating a portion of the thermosetting resin that lies between the surface of the base and the first principal surface.

According to the electronic component and the electronic component package of at least one embodiment of the technology, it is possible to achieve superior handleability. Further, the method of manufacturing the electronic component of at least one embodiment of the technology makes it possible to manufacture such an electronic component achieving superior handleability.

It is to be noted that the effects of embodiments of the technology are not limited thereto, and may be any effects described above.

Although the technology has been described hereinabove in terms of the example embodiment and modification examples, it is not limited thereto. It should be appreciated that variations may be made in the described example embodiment and modification examples by those skilled in the art without departing from the scope of the disclosure as defined by the following claims. The limitations in the claims are to be interpreted broadly based on the language employed in the claims and not limited to examples described in this specification or during the prosecution of the application, and the examples are to be construed as non-exclusive. The use of the terms first, second, etc. do not denote any order or importance, but rather the terms first, second, etc. are used to distinguish one element from another. The term “substantially” and its variants are defined as being largely but not necessarily wholly what is specified as understood by one of ordinary skill in the art. The term “disposed on/ provided on/formed on” and its variants as used herein refer to elements disposed directly in contact with each other or indirectly by having intervening structures therebetween. Moreover, no element or component in this disclosure is intended to be dedicated to the public regardless of whether the element or component is explicitly recited in the following claims.

What is claimed is:

1. An electronic component comprising:
a body including a first side surface, a second side surface opposite to the first side surface, and a first principal surface; and
one or more protrusions, the one or more protrusions being provided on at least one of the first side surface, the second side surface, or the first principal surface.

2. The electronic component according to claim 1, wherein
the body further includes a second principal surface opposite to the first principal surface, and
the one or more protrusions are provided also on the second principal surface.

3. The electronic component according to claim 2, wherein
the body further includes a third side surface that couples the first side surface and the second side surface to each other, and a fourth side surface opposite to the third side surface, and
the one or more protrusions are provided also on the third side surface, the fourth side surface, or both.

4. The electronic component according to claim 3, further comprising an electrode provided on at least one of the first principal surface, the first side surface, the second side surface, the third side surface, the fourth side surface, or the second principal surface of the body,
wherein the one or more protrusions are located off the electrode.

5. The electronic component according to claim 1, wherein the one or more protrusions each include an ultraviolet curable resin or a thermosetting resin.

6. The electronic component according to claim 1, wherein the one or more protrusions are provided on a first border part between the first side surface and the first principal surface, a second border part between the second side surface and the first principal surface, or both.

7. An electronic component package comprising:
an electronic component that includes:
a body including a first side surface, a second side surface opposite to the first side surface, and a first principal surface; and
one or more protrusions, the one or more protrusions being provided at least on at least one of the first side surface, the second side surface, or the first principal surface;
a container that includes a recessed part containing the electronic component, the recessed part including a first inner wall face that faces the first side surface of the body of the electronic component, and a second inner wall face that faces the second side surface of the body of the electronic component; and
a cover member covering the first principal surface of the body of the electronic component contained in the recessed part.

8. The electronic component package according to claim 7, wherein
the body of the electronic component further includes a second principal surface opposite to the first principal surface,
the one or more protrusions are provided also on the second principal surface, and
the recessed part further includes a bottom surface facing the second principal surface.

9. A method of manufacturing an electronic component that includes a body and one or more protrusions, the method comprising:
preparing a base that includes a surface and is transparent to ultraviolet radiation;
preparing a body array that includes a first principal surface and a second principal surface and includes a plurality of the bodies, the bodies being arranged side by side along the first principal surface and the second principal surface;
putting an ultraviolet curable resin on the surface of the base, the first principal surface of the body array, or both, and attaching the first principal surface of the body array to the surface of the base with the ultraviolet curable resin interposed therebetween;
cutting the body array attached to the base with the ultraviolet curable resin interposed therebetween and thereby separating every adjacent two of the bodies from each other;
irradiating the first principal surface with first ultraviolet light through the base; and
irradiating the second principal surface with second ultraviolet light from a side opposite to the base as viewed from the bodies to cure a first portion of the ultraviolet curable resin that adheres to the first principal surface, and thereby forming a first one of the one or more protrusions on the first principal surface.

10. The method according to claim 9, further comprising removing, by washing with water, a second one of the one or more protrusions that results from a second portion of the ultraviolet curable resin adhering to the second principal surface and thereafter curing by irradiation of the second principal surface with the second ultraviolet light.

11. The method according to claim 9, wherein the irradiating of the first principal surface with the first ultraviolet light and the irradiating of the second principal surface with the second ultraviolet light result in curing of a third portion of the ultraviolet curable resin that adheres to a border part between a side surface of each of the bodies formed by the cutting and the first principal surface intersecting the side surface, and thereby further form a third one of the one or more protrusions on the border part.

12. The method according to claim 9, wherein the second ultraviolet light is made higher in intensity than the first ultraviolet light.

13. A method of manufacturing an electronic component that includes a body and one or more protrusions, comprising:
preparing a base including a surface;
preparing a body array that includes a first principal surface and a second principal surface and includes a plurality of the bodies, the bodies being arranged side by side along the first principal surface and the second principal surface;
putting a thermosetting resin on the surface of the base, the first principal surface of the body array, or both, and attaching the first principal surface of the body array to the surface of the base with the thermosetting resin interposed therebetween;
cutting the body array attached to the base with the thermosetting resin interposed therebetween and thereby separating every adjacent two of the bodies from each other;
forming the one or more protrusions by applying heat to at least one of: a portion of the thermosetting resin that adheres to a side surface of each of the bodies formed by the cutting; a portion of the thermosetting resin that lies at a border part between the side surface and the first principal surface; or a portion of the thermosetting resin that adheres to the second principal surface; and
heating a portion of the thermosetting resin that lies between the surface of the base and the first principal surface.
